(19) United States
(12) Patent Application Publication
(10) Pub. No.: US 2016/0196927 A1
(43) Pub. Date: Jul. 7, 2016

(54) OPTO-ELECTRONIC DEVICE MODULE AND METHOD FOR MANUFACTURING THE SAME

(71) Applicant: SWANSEA UNIVERSITY, Swansea (GB)

(72) Inventors: Daniel Bryant, Swansea (GB); Peter Greenwood, Singleton Park, Swansea (GB); Maarten Wijdekop, Wrexham (GB); Udaya Shantha Ketipearachchi, South Yorkshire (GB); Paolo Melgari, Durham (GB)

(21) Appl. No.: 14/916,324

(22) PCT Filed: Aug. 29, 2014
(86) PCT No.: PCT/GB2014/000341

§ 371 Date: Mar. 3, 2016

(30) Foreign Application Priority Data
Sep. 5, 2013 (GB) 1315869.6

(51) Int. Cl. H01G 9/20; H01L 51/00

(52) U.S. Cl. CPC H01G 9/2018; H01G 9/2059; H01G 9/2081; H01L 51/0037; H01L 51/004

(57) ABSTRACT

The present invention relates to a module of opto-electronic devices, which comprises a plurality of opto-electronic devices arranged on a first electrically insulating carrier substrate to define a plurality of interconnection regions between the opto-electronic devices, with each opto-electronic device comprising: —an upper device component that comprises a second electrically insulating carrier substrate and a counter electrode made of a metal, a conductive oxide or a conductive organic compound; —a lower device component that comprises a working electrode, a blocking layer, an active layer, a hole conducting layer and a lower contact layer, and —a conductive adhesive disposed between the upper device component and the lower device component, wherein the conductive adhesive disposed between the upper device component and the lower device component is a transparent conductive adhesive and an interconnecting conductive adhesive is provided in each interconnection region between, and in electrical contact with, the counter electrode of one opto-electronic device and a working electrode of an adjacent opto-electronic device for interconnecting the opto-electronic devices in series.

The present invention relates to a module of opto-electronic devices and to a method for manufacturing the same.

Opto-electronic devices encompass photovoltaic (PV) devices that convert light into electricity and organic light emitting diodes (OLEDs) that emit light in response to an electrical current.

Dye sensitised solar cells (DSCs) are examples of PV devices that were first developed by Prof Michael Gräzel and co-workers (Nature, 353 (24) 737-740) as alternatives to expensive crystalline silicon PV devices. DSCs typically comprise an active layer for converting light into electricity, a working electrode (or anode) for receiving electrons from the active layer and a counter electrode (or cathode), which receives and transports electrons back to the active layer via a liquid electrolyte. An important drawback of DSC devices making use of a liquid electrolytes is that they lack long term stability due to the volatility of the electrolyte contained in an organic solvent. Another disadvantage is that the electrolyte is temperature sensitive, which may lead to physical damage of the device if the temperature Is too low, or to problems sealing the device due to expansion of the electrolyte if the temperature is too high.

In view of the above disadvantages, attention has recently switched from DSC devices containing liquid electrolytes to solid state ‘hybrid’ PV devices, where the liquid electrolyte is replaced by a solid hole transporting material (HTM). Examples of hybrid PV devices include solid state dye sensitised solar cells (sDSC), perovskite/metal-oxide heterojunction solar cells, mesoscopic solar cells (meso-superstructured solar cells, MSSC's) and ‘thin film’ or ‘flat junction’ perovskite solar cells, which are characterised by extremely thin absorber (ETA) layers. Such hybrid PV devices typically comprise a lower device component that comprises a working electrode, a blocking layer, an active layer and a solid hole transport material, and an upper device component that comprises a counter electrode. While progress has been made to deposit the lower device component materials using atmospheric processes such as printing, the counter electrode is typically provided by sputtering silver or ITO directly onto the hole transport material. However, sputtering is a vacuum based deposition process and therefore this method prevents a low cost roll-to-roll production process for manufacturing hybrid devices on a commercial scale.

The use of solid hole transporting materials over liquid electrolytes has inherent practical advantages but also results in improved device conversion efficiencies. Nevertheless, it is still necessary to electrically interconnect the hybrid PV devices in series in order tc obtain a useful output voltage, which may be achieved by making electrical contact between the working electrode of one device and the counter electrode of an adjacent device using conductive interconnects.

Soldering is a method that is often used to interconnect adjacent hybrid PV devices since such interconnects (metallic) have both a low bulk resistance and a low contact resistance with the electrodes, so that resistive losses are kept to a minimum. However, soldering suffers from the disadvantage that it is a high temperature process and therefore the risk of damaging the active materials of the hybrid PV devices is significantly increased.

Interconnection between adjacent opto-electronic devices may also be achieved by employing a low pressure encapsulation process where the working electrode of one device and the counter electrode of an adjacent device are forced together under mechanical pressure. However, a disadvantage of this method is that it is expensive and results in a slow manufacturing process that could incur regular delays.

It an object of the present invention to provide a low cost method for manufacturing opto-electronic devices such as hybrid PV devices.

It is an object of the present Invention to provide a continuous roll-to-roll method for manufacturing opto-electronic devices such as hybrid PV devices.

It is another object of the present invention to provide an improved production process for manufacturing modules of interconnected opto-electronic devices.

According to a first aspect of the invention one or more of the above objects are reached by providing a module of opto-electronic devices, which comprises a plurality of opto-electronic devices arranged on a first electrically insulating carrier substrate to define a plurality of interconnection regions between the opto-electronic devices, with each opto-electronic device comprising:
an upper device component that comprises a second electrically insulating carrier substrate and a counter electrode made of a metal, a conductive oxide or a conductive organic compound;
a lower device component that comprises a working electrode, a blocking layer, an active layer, a hole conducting layer and a lower contact layer, and
a conductive adhesive disposed between the upper device component and the lower device component, wherein the conductive adhesive disposed between the upper device component and the lower device component is a transparent conductive adhesive and an interconnecting conductive adhesive is provided in each interconnection region between, and in electrical contact with, the counter electrode of one opto-electronic device and a working electrode of an adjacent opto-electronic device for interconnecting the opto-electronic devices in series.

The inventors found that opto-electronic devices of the present invention and modules thereof could be manufactured using low-cost, atmospheric, roll-to-roll manufacturing processes, without compromising the efficiency and output voltage of the opto-electronic devices and modules respectively. By providing the transparent conductive adhesive opto-electronic devices could be manufactured using a laminating process and therefore the step of sputtering the counter electrode on the hole conducting layer could be avoided. In addition to providing a strong mechanical bond between the upper device component and the lower device component after laminating, the transparent conductive adhesive has the additional effect of enhancing electrical contact between the counter electrode and the hole conducting layer such that good conversion efficiencies could be obtained. Further improvements in conversion efficiency are obtained when the opto-electronic device comprises the lower contact layer between and in contact with the transparent conductive adhesive and the hole conducting layer. This Is because the lower contact layer further enhances the conductivity in the z-direction, i.e. In the direction perpendicular to the plane of the device. This is important, because if resistive losses in the z-direction are too high, the overall efficiency of the device is compromised.

By providing the interconnecting conductive adhesive, opto-electronic devices could be connected in series and useful output voltages could be obtained. The interconnecting conductive adhesive was provided in contact with the counter electrode of one opto-electronic device and the working electrode of an adjacent opto-electronic device. The interconnecting conductive adhesive of the present invention is not metallic and therefore the use of high processing temperatures, which could damage the active materials of the devices, is avoided. The use of non-metallic interconnects has the additional advantage that interconnect material costs are kept to a minimum and associated corrosion issues are avoided.

The purpose of the blocking layer is to prevent electrons from the working electrode recombining with holes in the hole conducting layer located in the pores of the active layer. The blocking layer preferably comprises a dense metal oxide such as TiO₂. Other suitable blocking layer materials include zinc oxide (ZnO) and tin oxide (SnO₂). Preferably the blocking layer has a layer thickness between 2 and 100 nm.

The active layer preferably comprises a nanoporous metal oxide that is coated with a light absorbing dye or a light absorbing inorganic material. In a preferred embodiment the active layer is formed by (i) applying a paste on the blocking layer, the paste comprising a solvent, a binder and metal oxide particles, (ii) heating the applied paste to a temperature that is chosen to remove the solvent and the binder and (iii) sintering the metal oxide at a temperature between 400° C. and 600° C. so as to interconnect the metal oxide particles and form a nanoporous structure. Suitable metal oxide materials include Al₂O₃, SnO₂ and TiO₂, with TiO₂ being particularly preferred. The sintered metal oxide is subsequently coated with a light-absorbing dye or light absorbing inorganic material. Preferred sensitising dyes comprise ruthenium complexes and phthalocyanines. Preferred light absorbing inorganic materials are perovskite compounds. Since the metal oxide is sintered at a temperature between 400° C. and 600° C., the previously provided layers, i.e. the carrier substrate, the working electrode and the blocking layer, should also be thermally stable between 400 and 600° C. In view of this requirement, the use of TCO-coated glass carrier substrates is preferred. Other suitable active layers comprise organic compounds only, e.g. a mixture of poly(3-hexylthiophene) (P3HT) and a fullerene derivative such as 6,6-phenyl C61-butyric acid methylester (PCBM). Alternatively, the organic semi-conductor may comprise conjugated polymers such as phthalocyanine, polyacetylene, poly(phenylene vinylene) or derivatives thereof.

The hole conducting layer preferably comprises a hole transport material such as 2,2′,7,7-tetrakis-(N,N-di-p-methoxyphenyl-amine)9,9′-spirobifluorene (hereinafter referred to as Spiro-OMeTAD). The use of the hole transport material instead of conventional liquid electrolytes has the advantage that issues surrounding the sealing of the liquid electrolyte are avoided. Spiro-OMeTAD is particularly preferred as an organic hole transport material since a good electrical match exists between the energy levels of Spiro-OMeTAD and the material of the active layer. It is preferred to use a Spiro-OMeTAD hole transport material when the material of the active layer comprises a dye sensitised metal oxide such as TiO₂ or a perovskite coated metal oxide.

An upper contact layer may be provided between the counter electrode and the transparent conductive adhesive to improve the conductivity in the z-direction. The observed improvement has been attributed to the upper contact layer facilitating the extraction of electrons from the counter electrode and their subsequent injection into the transparent conductive adhesive. The upper contact layer is preferably provided when the opto-electronic device comprises a non-metallic counter electrode such as conductive oxides (ITO/FTO) in order to provide better electrical contact between the transparent conductive adhesive and the non-metallic counter electrode materials, or to improve the lateral conductivity of the counter electrode when a metallic grid with a wide pitch (>2 mm) is used in combination with a transparent conductive adhesive.

A second upper contact layer may be provided in the interconnection region between the counter electrode and the interconnecting conductive adhesive. By providing the second upper contact layer, electrical contact between the counter electrode and the interconnecting conductive adhesive is improved. This improvement has been attributed to the second contact layer facilitating the extraction of electrons from the interconnecting conductive adhesive and their subsequent injection into the counter electrode. Preferably the second upper contact layer is only provided when the counter electrode comprises a conductive oxide such as FTO or ITO. In such cases the bulk conductivity of the counter electrode and the electrical contact with the interconnecting conductive adhesive is not optimal, and therefore the second upper contact layer is provided to enhance the lateral conduction of electrons as well as conductivity in the z-direction. On the other hand, when the counter electrode material is metallic, e.g. in the form of a nickel grid with a gold finish or a fine metallic grid with a pitch of 300 μm, it is not necessary to provide the second upper contact layer since the metallic counter electrode already exhibits very good lateral conductivity and good electrical contact with the interconnecting conductive adhesive.

An interconnect contact layer may be provided in the interconnect region between the interconnecting conductive adhesive and the blocking layer. The interconnect contact layer improves the lateral conduction of electrons and the electrical contact of the blocking layer with the interconnecting conductive adhesive. This increases the conductivity in the z-direction by facilitating the extraction of electrons from the working electrode and their subsequent injection into the interconnecting conductive adhesive.

One or more of the lower contact layer, upper contact layer, second upper contact layer and interconnect contact layer preferably comprise a conductive polymer. Particularly preferred conductive polymers include:

poly(3,4-ethylenedioxythiophene) poly(styrenesulfonate) (PEDOT:PSS);

polythiophenes;

polyanilines, and

polypyroles

These conductive polymers and their derivatives are particularly suitable for use as lower contact layer and upper contact layer materials in view of their transparency. If the lower contact layer and/or the upper contact layer comprises translucent or opaque materials, a greater proportion of light is not able to reach the active layer of the device and reduced conversion efficiencies are obtained. For the lower contact layer and the upper contact layer, it has been found that PEDOT:PSS is very suitable for facilitating the transport of electrons in the z-direction, both from the counter electrode to the transparent conductive adhesive in the case of the upper contact layer and from the transparent conductive adhesive to the hole conducting layer in the case of the lower contact layer. Non-aqueous PEDOT:PSS solutions are preferably used when depositing the lower contact layer in view of the sensitivity of the hole conducting layer to water.

The above conductive polymers are also very suitable for use as second upper contact layer and interconnect contact layer materials. Since the second upper contact layer and the interconnect contact layer are provided in the interconnect region, the requirement for these layers to be transparent is avoided. Nevertheless, the above conductive polymers, particularly PEDOT:PSS, are very suitable for facilitating the transport of electrons, both laterally and in the z-direction. From a manufacturing perspective, and in the event the upper contact layer and the second upper contact layer are provided, it is particularly preferred that the upper contact layer and the second upper contact layer comprise the same materials, e.g. PEDOT:PSS, since these materials can be deposited in a complimentary pattern in a single processing step as part of a continuous roll-to-roll manufacturing process, for example by screen printing or gravure printing. Similarly, and for the same reason, it is preferred that the lower contact layer and the interconnect contact layer comprise the same materials, preferably PEDOT:PSS.

As an adhesive material, the transparent conductive adhesive preferably comprises polyacrylates or derivatives thereof. Polyacrylates are preferred since they are transparent and because a strong mechanical bond is formed between the upper device component and the lower device component after lamination. In order to impart conductivity to the adhesive, the adhesive is preferably mixed with a conductive polymer selected from the group consisting of:

poly(3,4-ethylenedioxythiophene) poly(styrenesulfonate) (PEDOT:PSS);

polythiophenes;

polyanilines, and

polypyroles

These conductive polymers and/or their derivatives are preferred since they are transparent, exhibit good conductivity and can be mixed with the adhesive without further modification of either the adhesive or the conductive polymer. When the transparent conductive adhesive comprises PEDOT:PSS, good conductivity in the z-direction can obtained particularly between the lower contact layer and the transparent conductive adhesive, especially when the lower contact layer also comprises PEDOT:PSS.

Preferably the transparent conductive adhesive comprises at least 0.3 wt %, preferably between 1-10 wt %, more preferably between 1-5 wt % of the conductive polymer. It was found that transparent conductive adhesives comprising at least 0.3 wt % of the conductive polymer exhibited improved conductivity in the z-direction relative to the transparent adhesive itself. When the conductive polymer content was increased to between 1 and 5 wt % a bulk conductivity of between 0.5 and 30 Siemens/cm was obtained. A bulk conductivity of between 0.01 and 30 Siemens/cm is sufficient for obtaining good z-conduction between the current collector and the active layer. Although the bulk conductivity of the transparent conductive adhesive can be increased further by providing 10 wt % of the conductive polymer, it is preferred not to exceed 10 wt % since this may result in a reduction in the transparency of the transparent conductive adhesive.

In a preferred embodiment the lower contact layer, the transparent conductive adhesive and the upper contact layer and the interconnect contact layer comprise PEDOT:PSS.

Preferably the transparent conductive adhesive and the interconnecting conductive adhesive comprise the same materials. This has the advantage that the transparent conductive adhesive and the interconnecting conductive adhesive can be deposited in a complimentary pattern in a single processing step as part of a continuous roll-to-roll manufacturing process, for example by screen printing or gravure printing. Preferably the transparent conductive adhesive and the interconnecting conductive adhesive comprise a polyacrylate adhesive and PEDOT:PSS.

Unlike the transparent conductive adhesive, the requirement for the interconnecting conductive adhesive to be transparent is avoided since the interconnecting conductive adhesive is provided in the interconnect region and does not form part of an opto-electronic device. This has the advantage that the adhesive and the conductive materials of the interconnecting conductive adhesive may be chosen from a greater variety of materials. For instance, the interconnecting conductive adhesive may comprise an adhesive material and a conductive material comprising metal or metal alloy particles for the purpose of conducting electrons in the z-direction. Similarly, the interconnecting conductive material may comprise conductive polymers or allotropes of carbon such as carbon nanotubes, carbon black or graphite for the purpose of providing conduction in the z-direction.

The working electrode preferably comprises a metallic sheet or foil. Plated metallic sheets or foils are particularly preferred since improvements in conversion efficiency can be realised because of the low sheet resistance of the metallic sheet or foil. This has also been attributed, at least in part, to the low surface roughness of the plating layer that contributes to reducing the occurrence of electrical shorting in the device. A further advantage is that the plating layer prevents or at least reduces oxidation of the metal substrate when the metal substrate is exposed to elevated temperatures e.g. during a sintering process, by preventing exposure of the metal substrate to oxygen in air. Finally, by using plated metallic substrates as working electrodes, the requirement for more expensive working electrode materials such as titanium foils or vacuum sputtered titanium or titanium alloys (TiN) on stainless steel substrates Is avoided. Preferably the working electrode is an electrolytic chrome-coated steel (ECCS). Preferably the thickness of the plating layer comprising chromium and chromium oxide is between 5 and 25 nm.

The working electrode preferably comprises a metallic coating on a polymeric film, since this combination is light-weight and provides a low sheet resistance. Metallic coatings such as Al, Cr, Ti, Ni, Cu, Ag, Au and Mo are very suitable as working electrodes and can easily be applied on polymeric substrates such as PET and PEN. Metallic coatings additionally provide good barrier properties to oxygen and water vapour.

The working electrode preferably comprises a coating that comprises a polymeric material, e.g. polyimide and allotropes of carbon such as carbon nanotubes, graphite, carbon black, fullerenes or mixtures thereof that are dispersed in a polymeric material. Alternatively the working electrode may comprise a conductive polymeric coating, e.g. PEDOT:PSS or a coating that comprises metal or metal alloy particles.

The working electrode preferably comprises a transparent conductive oxide such as ITO or FTO, or a stack of conductive oxides with an optional thin (<10 nm) metallic layer such as silver. Electrically insulating glass carrier substrates with transparent conductive coatings can be produced in cost-effective chemical vapour deposition (CVD) or physical vapour deposition (PVD) processes, having an average surface roughness of less than 100 nm, which helps minimise the occurrence of electrical shorts. Additional advantages of using glass carrier substrates with a transparent conductive coating is that they are highly transparent (>80%), and therefore a significant portion of light is able to reach the active layer of the device. Electrically insulating carrier substrates made of float glass are particularly preferred.

The counter electrode is preferably provided on the surface of the second electrically insulating carrier substrate, which should be transparent so that light can enter the opto-electronic device. In this embodiment the counter electrode comprises metallic inks, e.g. silver or copper. Such metallic inks are printable and therefore the counter electrode can be applied as part of a fast and continuous manufacturing route. Gravure-printing, flexographic printing or screen-printing are preferred means for printing such metallic inks. Once printed, the inks can be cured in a convection oven or by electromagnetic radiation; near infrared (NIR) curing is particularly preferred.

The counter electrode, preferably in the form of a metallic grid, may also be embedded in the second electrically Insulating carrier substrate, resulting in a smooth and flat surface that is very suitable for subsequent coating, e.g. with the transparent conductive adhesive or the upper contact layer. By having a smooth and flat surface, the mechanical and electrical contact between the counter electrode and the subsequent coating is improved. Since the counter electrode is metallic, the counter electrode affords better bulk conductivity than conductive oxides and cured metallic inks comprising sintered metallic particles. Preferably the metallic grid counter electrode comprises multiple layers in order to achieve a good balance between cost, performance and durability. For instance the metallic grid counter electrode may comprise a gold sub-layer in order to provide durability and good contact with the second transparent conducive layer, a copper sub-layer as an inexpensive bulk conductor and a nickel intermediate sub-layer to facilitate the electroplating of the copper sub-layer onto the gold sub-layer.

Preferably the counter electrode is in the form of a free-standing mesh. Preferably the mesh is made by weaving metal or metal alloy wires, by removing holes from a metal or metal alloy substrate e.g. steel foil or sheet, by laser or mechanical cutting, by electroplating or by 3D printing.

The first electrically insulating carrier substrate and/or the second electrically insulating carrier substrate preferably comprise glass, an insulating polymeric film or a metallic carrier substrate provided with an electrically insulating coating.

According to a second aspect of the invention there is provided a method for manufacturing a module of opto-electronic devices according to any one of the preceding claims, which comprises the steps of:
providing a lower device component on a first electrically insulating carrier substrate in a first pattern to define a plurality of device regions and interconnection regions on the first electrically insulating carrier substrate, the lower device component comprising a working electrode, a blocking layer, an active layer, a hole conducting layer and a lower contact layer;
providing an upper device component that comprises a second electrically insulating carrier substrate and a counter electrode;
providing a transparent conductive adhesive on the upper device component in a second pattern to define a plurality of device regions and interconnection regions on the upper device component;
providing an interconnecting conductive adhesive in the interconnection regions of the upper device component;
curing the transparent conductive adhesive and the interconnecting conductive adhesive, and
aligning the device regions and interconnecting regions of the upper device component with the device regions and interconnecting regions of the lower device component and laminating the upper device component and the lower device component to form a module of opto-electronic devices that are electrically interconnected in series.

This method has the advantage that the use of high temperatures such as those used when soldering metallic interconnects is avoided. This additionally enables modules of opto-electronic devices to be manufactured at low cost. A further advantage is that opto-electronic device modules can be produced using a continuous roll-to-roll manufacturing process.

In a preferred embodiment the transparent conductive adhesive and the interconnecting conductive adhesive are made of the same material and are deposited in a single processing step. This has the advantage of increasing the speed at which the opto-electronic device modules can be manufactured.

Preferably the lower contact layer and an interconnect contact layer provided in the interconnection region on the blocking layer are made of the same materials and are deposited in single processing step. By providing the interconnect contact layer electrical contact between the working electrode and the interconnecting conductive adhesive may be enhanced. From a manufacturing perspective, the use of the same material for the lower contact layer and the Interconnect contact layer enables the respective layers to be deposited using a single processing step, thereby increasing the overall speed of the manufacturing process.

The invention will be now be elucidated by referring to the non-limitative examples below.

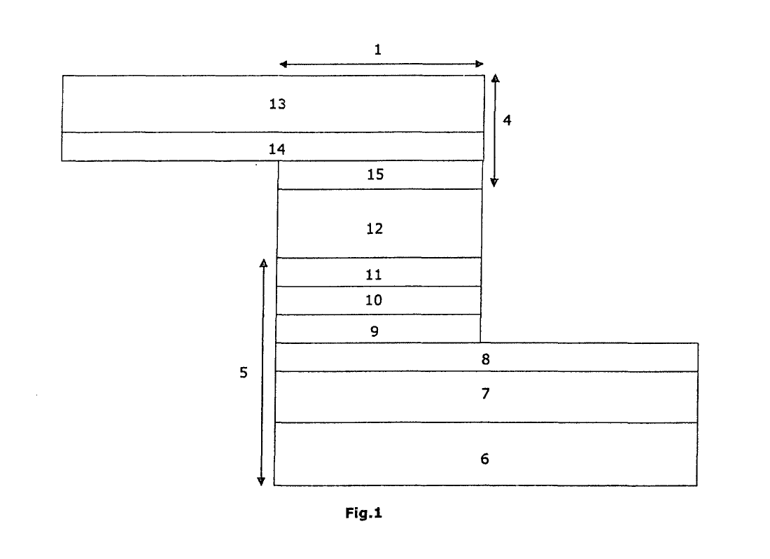

FIG. 1 shows a first solar cell (1) comprising an upper device component (4) that consists of an electrically insulating upper carrier substrate (13), a counter electrode (14) and an upper contact layer (15). The solar cell also comprises a lower device component (5) consisting of an electrically insulating lower carrier substrate (6), a working electrode (7), a blocking layer (8), an active layer (9), a hole conducting layer (10) and a lower contact layer (11). A transparent conductive adhesive (12) is disposed between the upper device component and the lower device component for providing electrical contact between the upper device component and the lower device component.

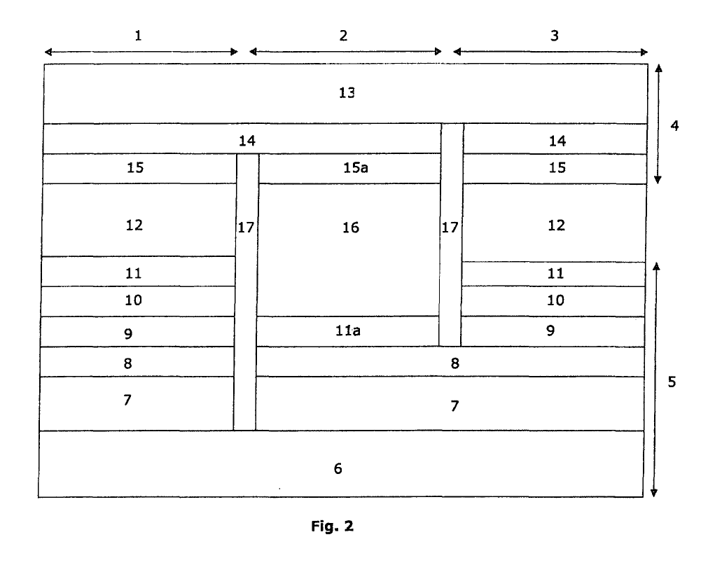

FIG. 2 shows a solar cell module comprising two solid state solar cells connected in series. The module comprises a first solar cell (1), an interconnect region (2) and a second solar cell (3). An upper device component (4) consists of an electrically insulating upper carrier substrate (13), a counter electrode (14) and an upper contact layer (15). A lower device component (5) consists of an electrically insulating lower carrier substrate (6), a working electrode (7), a blocking layer (8), an active layer (9), a hole conducting layer (10) and a lower contact layer (11). A transparent conductive adhesive (12) is disposed between the upper device component and the lower device component for providing electrical contact between the upper device component and the lower device component.

The counter electrode (14) of the first solar cell (1) may be electrically connected to the working electrode (7) of the second solar cell (3) via an interconnecting conductive adhesive (16). Electrical contact between the interconnecting conductive adhesive and the working electrode can be improved by providing an interconnect contact layer (11a). Similarly, electrical contact between the interconnecting conductive adhesive and the counter electrode can be improved by providing a second upper contact layer (15a). An electrically insulating sealant or spacer, or an air gap (17) separates the first and the second solar cell from the interconnect region in order to prevent electrical shorting.

In a first example (A) the lower device component (5) comprises an electro-chromium coated steel (ECCS) foil as the working electrode (7). The ECCS foil, had a thickness of 150 μm, a ‘fine stone’ surface finish and on each side of the foil a chromium coating (140 mg/sqm), of which 35 mg/sqm was chromium oxide. The surface roughness of the ECCS foil was 0.25 urn as measured in accordance with ASTM D7127.

The ECCS foil was cleaned with acetone and isopropyl alcohol (IPA) to remove dirt and oxides. A blocking layer (8) was provided on the cleaned ECCS foil by depositing a thin dense (non-porous) TiO₂ coating on the ECCS foil with a multi-pass spray pyrolysis process. The TiO₂ coating was deposited from a Ti (IV) isopropoxide solution and during the deposition, the ECCS foil was heated to a temperature above 200° C. The coated ECCS foil was then heated in an IR oven for 2.5 minutes to sinter the applied TiO₂ layer, thereby forming the blocking layer (8) which is virtually pin-hole free. The thickness of the blocking layer after sintering was approximately 50 nm.

Subsequently, a TiO₂ containing paste (DSL18NRT, Dyesol) was screen-printed on the blocking layer (8) and sintered at 500° C. for 150 seconds in an Infrared (IR) oven to obtain a nano-porous TiO₂ layer. The dry film thickness of the sintered TiO₂ layer was measured to be around 2 μm.

The coated ECCS foil comprising the blocking layer (8) and the sintered TiO₂ layer was then immersed in a dye solution containing an organic dye (0.5 mMol of D102 (Mitsubishi Paper Mills Ltd) in a 1:1 mixture of tertiary butanol and acetonitrile). The coated ECCS foil was immersed in the dye solution for 60 minutes at room temperature and then rinsed with acetonitrile to remove any excess dye. The coated ECCS foil was then immersed in isopropyl alcohol (IPA) for 10 minutes and rinsed again with acetone to form a dye sensitised TiO₂ active layer (9).

A Hole Transport Material (HTM) solution containing spiro-OMeTAD (Luminescence Technology Corp.) in chloro-benzene (225 mg/ml) was prepared to which was added 47 μl of a LiN(SO₂CF₃)₂ stock solution (170 mg/ml in acetonitrile) and 22 μl of tert-butyl pyridine. 50 μL of this HTM solution was subsequently applied on the active layer (9). The HTM solution was allowed to penetrate the pores of the dye sensitised TiO₂ active layer for 60 seconds and to form a thin (<0.2 μm) hole conducting layer (10), before the excess was removed using a spin coater.

A lower contact layer (11) was provided on the hole conducting layer (10) to improve the electrical contact between the hole conducting layer and the transparent conductive adhesive (12). This lower contact layer comprised a bespoke PEDOT:PSS formulation from Heraeus Precious Metals GmbH & Co that was substantially water-free (<1%); this ‘dry’ PEDOT:PSS ink was bar coated on the surface of the hole conducting layer at a wet film thickness of 45 μm, and thereafter exposed to a temperature of 75° C. for 12 minutes.

For the upper device component (4), ‘Epimesh 300s Gold’ from Epigem Ltd was used. This product is a flexible transparent electrode, comprising a transparent polymer (PET) film as the second electrically insulating carrier substrate (13) and an embedded metallic mesh (nickel bulk with a gold finish, line width 5 μm, pitch 300 μm) as the counter electrode (14).

A transparent conductive adhesive (12) was prepared by mixing a PEDOT:PSS ink (EL-P-3145, Agfa) with an acrylic adhesive (Styccobond F46) In a 1.5:1 ratio by weight. This mixture was stirred for approximately two minutes and then subjected to a low pressure environment to remove entrapped air. The transparent conductive adhesive was then bar coated on the flexible transparent electrode. The applied transparent conductive adhesive had a wet film thickness of 90 microns.

The flexible transparent electrode, coated with the transparent conductive adhesive (12), was then subjected to a 60° C. heat treatment in a convection oven for fifteen minutes to remove any low boiling point solvents. The temperature was then Increased to 120° C. for five minutes to remove the higher boiling solvents in the transparent conductive adhesive. After curing, the transparent conductive adhesive exhibited a bulk conductivity of around 0.5 S/cm.

To form the solid state solar cells, the coated transparent electrode comprising the cured transparent conductive adhesive was manually laminated (at room temperature with 1 bar of mechanical pressure) on the lower device component (5), such that the transparent conductive adhesive was in contact with the ‘Epigem 300s Gold’ transparent electrode and the PEDOT:PSS lower contact layer (11).

To interconnect the solar cells, an interconnecting conductive adhesive (16) was prepared and applied on a portion of the counter electrode (14) of the upper device component (4) of the first solar cell (1) that extends into the interconnection region (2). In this example the same material was used for the interconnecting conductive adhesive and the transparent conductive adhesive (12). The applied interconnecting conductive adhesive had a wet film thickness of 90 μm and was exposed to the same curing profile as the transparent conductive adhesive.

Once the interconnecting conductive adhesive (16) had been cured, an exposed portion of the second solar cell (3) comprising the working electrode (7) and the blocking layer (8) was pressed onto the interconnecting conductive adhesive to electrically interconnect the first solar cell (1) and the second solar cell. In this embodiment the exposed portion of the second solar cell comprises the working electrode (7) and the blocking layer (8).

The individual performance of two solid state solar cells and a module thereof was assessed by taking their I-V (current-voltage) measurements using a class AAA Oriel Sol3A solar simulator and a Keithley Instruments Model 2400 source meter. This system uses a filtered Xenon Arc lamp and light filters to simulate sunlight equivalent to the intensity of light being produced at 1 sun (100 mW/cm2). The cells were tested from −0.8 to 1.0 V in order to obtain their short circuit current (J_{sc}) and the open circuit voltage (V_{oc}). The results were plotted as an I-V curve. From the obtained I-V curves, the efficiency and the Fill Factor (FF) can be determined.

The performance data of Example A is shown in Table 1. The first two rows show the performance data of a first solar cell and a second solar cell that were produced in accordance with the method hereinabove. The third row (in bold) shows the performance data of the solar cell module that was produced after the first solar cell and the second solar cell had been electrically interconnected.

Table 1 also shows the performance data of other solar cells and solar cell modules that were manufactured in accordance with the above method (Examples B-J). Unless stated, the devices of examples B-J comprise the same materials as those that were used to manufacture the devices of Example A.

Devices of example B were produced in the same way as in example A, except that the blocking layer was removed from the working electrode of the second solar cell before it was pressed onto the interconnecting conductive adhesive. The blocking layer was removed by manual abrasion using sand paper.

Devices of example C were produced in the same way as in example A, except that an interconnect contact layer (11a) made of a modified PEDOT:PSS was applied on the exposed blocking layer (8) portion before it was pressed onto the interconnecting conductive adhesive. The modified PEDOT:PSS interconnect contact layer was prepared by adding 0.1 g of Trinton X-100 (a surfactant supplied by Dow Chemical Company) to 1.9 g of ethylene glycol and then stirring this solution to form a solvent precursor (2 g). 0.2 g of the solvent precursor was then added to 2 g of PH1000 (a water-based PEDOT:PSS ink supplied by Heraeus Precious Metals GmbH & Co). This solution was stirred and then tape cast onto the exposed blocking layer of the second solar cell. To form the interconnect contact layer, the applied solution was dried in air for 2 minutes and then cured in a fan oven for 12 minutes at 75° C.

This procedure is thought to improve the surface tension or ‘wettability’ of the PEDOT:PSS ink when it is used as the interconnecting contact layer (11a), because it has to be applied directly to the blocking layer (8), which is a dense oxide.

The devices of examples D-J comprise fluorine-doped tin oxide (FTO) coatings as working electrodes (7). These FTO working electrodes were provided on glass, which acts as the first electrically insulating carrier substrate (6). The FTO coating has a sheet resistance of around 10 Ohms per square and was deposited using a CVD process.

The devices of examples D-F comprise a dense TiO₂ blocking layer (8) (thickness <10 nm) that was deposited onto the FTO coating using a CVD process, whereas the devices of examples G-J comprise a dense SnO₂ blocking layer (thickness between 10 nm and 100 nm) that was deposited on the FTO coating by a CVD process.

For examples D and G, interconnection between two the solar cells was achieved by pressing an exposed portion of the blocking layer (8) of the second solar cell (3) onto the interconnecting conductive adhesive (16).

For examples E and H interconnection between two solar cells was achieved by applying a silver paint (RS Components, UK) onto an exposed portion of the blocking layer (8) of the second solar cell (3). The paint was dried to form the interconnect contact layer (11a), before the exposed portion comprising the blocking layer and the dried silver paint was pressed onto the interconnecting conductive adhesive (16).

For examples F and I interconnection between two solar cells was achieved by applying a PEDOT:PSS coating (identical to that used in cell C) onto the exposed portion of the blocking layer (8) of the second solar cell (3). The PEDOT:PSS coating was cured to form the interconnect contact layer (11a) and then the exposed portion comprising the blocking layer and PEDOT:PSS interconnect contact later was pressed onto the interconnecting conductive adhesive.

For example J, interconnection between two solar cells was achieved by applying a bespoke substantially water free PEDOT:PSS formulation (<1% water) onto the exposed portion of the blocking layer (8) of the second solar cell, identical to that used for the lower contact layer (11) in all the cells. This bespoke ‘dry’ PEDOT:PSS coating was cured to form the interconnect contact layer (11a) and then the exposed portion comprising the blocking layer and PEDOT:PSS interconnect contact later was pressed onto the interconnecting conductive adhesive. The use of the ‘dry’ PEDOT:PSS coating as an interconnect contact layer is advantageous for industrial production, since both the lower contact layer and interconnect contact layer can be printed onto the lower device component in a complimentary pattern in a single process.

TABLE 1

| | Area | V_{oc} | J_{sc} | Fill | Efficiency |
|---|---|---|---|---|---|
| Example | (cm²) | (V) | (mA/cm²) | Factor | (%) |
| A | 1.2 | 0.693 | 4.46 | 0.424 | 1.31 |
| | 1.2 | 0.682 | 3.97 | 0.427 | 1.15 |
| | 2.4 | 1.262 | 2.06 | 0.453 | 1.18 |
| B | 1.0 | 0.779 | 5.95 | 0.420 | 1.95 |
| | 1.0 | 0.738 | 5.88 | 0.393 | 1.71 |
| | 2.0 | 1.508 | 2.11 | 0.444 | 1.41 |
| C | 1.0 | 0.710 | 4.48 | 0.287 | 0.91 |
| | 1.0 | 0.746 | 3.76 | 0.300 | 0.84 |
| | 2.0 | 1.408 | 1.80 | 0.304 | 0.77 |
| D | 1.2 | 0.789 | 10.22 | 0.335 | 2.70 |
| | 1.2 | 0.791 | 10.71 | 0.302 | 2.56 |
| | 2.4 | 1.538 | 0.54 | 0.148 | 0.12 |
| E | 1.2 | 0.789 | 10.22 | 0.335 | 2.70 |
| | 1.2 | 0.791 | 10.71 | 0.302 | 2.56 |
| | 2.4 | 1.487 | 3.26 | 0.358 | 1.74 |
| F | 1.0 | 0.688 | 6.47 | 0.344 | 1.53 |
| | 1.0 | 0.736 | 6.88 | 0.370 | 1.88 |
| | 2.0 | 1.408 | 3.12 | 0.396 | 1.62 |
| G | 0.8 | 0.746 | 5.27 | 0.368 | 1.45 |
| | 0.8 | 0.742 | 5.83 | 0.340 | 1.47 |
| | 1.6 | 1.312 | 1.40 | 0.278 | 0.51 |
| H | 0.8 | 0.768 | 3.99 | 0.358 | 1.10 |
| | 0.8 | 0.784 | 5.95 | 0.323 | 1.50 |
| | 1.6 | 1.384 | 1.42 | 0.373 | 0.74 |
| I | 1.0 | 0.736 | 4.78 | 0.368 | 1.30 |
| | 1.0 | 0.784 | 6.77 | 0.367 | 1.95 |
| | 2.0 | 1.504 | 2.68 | 0.393 | 1.59 |
| J | 0.8 | 0.768 | 6.20 | 0.383 | 1.83 |
| | 0.8 | 0.736 | 6.42 | 0.330 | 1.56 |
| | 1.6 | 1.440 | 2.62 | 0.363 | 1.37 |

The results show that for opto-electronic devices manufactured in accordance with Example A, a module efficiency of 1.18% was obtained. When the TiO₂ blocking layer was removed from the ECCS working electrode in the interconnect region, the module efficiency was increased to 1.41% (Example B). It is thought that Module B showed a higher open circuit voltage than module A (1.508 V versus 1.262 V) because the resistance of the blocking layer is removed from the interconnection. However, the selective removal of the blocking layer in a production line is not practical and therefore, from a manufacturing perspective, it is preferable not to remove the blocking layer in the interconnect region despite the efficiency improvements that can be gained.

For Module C, the blocking layer on the ECCS was left intact in the interconnecting region, but here the modified PEDOT:PSS ink was applied as the interconnect contact layer. This resulted in an open circuit voltage of 1.408 V, which is higher than the 1.262 V observed for Module A, demonstrating that the interconnect contact layer improves the electrical contact by reducing the work function mismatch between the interconnecting conductive adhesive and the blocking layer.

Module D, based on an FTO working electrode on a glass substrate with a TiO₂ blocking layer, has a very low current (0.54 mA/cm2) and a very low Fill Factor (FF, 0.148), indicating that the electrical contact between the TiO₂ blocking layer and the interconnecting conductive adhesive Is poor. When silver paint was applied on the TiO₂ blocking layer as an interconnect contact layer in Module E, the short circuit current and FF improved 3.26 mA/cm2 and 0.358 respectively.

In Module F, where the modified PEDOT:PSS ink was used again as the interconnect contact layer between the TiO₂ blocking layer and the interconnect conductive adhesive, a FF of 0.396 was demonstrated, indicating a lower series resistance in the interconnect region.

Module G, again based on an FTO-glass working electrode substrate but now with a SnO₂ blocking layer, shows a low short circuit current (1.40 mA/cm2) and a low FF (0.278). When the silver paint was applied onto the SnO₂ blocking layer as the interconnect contact layer in Module H, the FF improved to 0.373, but the short circuit current was still low (0.142 mA/cm2).

In Module I, introducing the modified PEDOT:PSS ink as the interconnect contact layer on the SnO₂ blocking layer showed a better short circuit current (2.68 mA/cm2), a better FF (0.393) and a better open circuit voltage (1.504 V) than modules G and H, demonstrating that introducing a PEDOT:PSS interconnect contact layer improves the overall module performance significantly.

In Module J, the bespoke dry PEDOT:PSS ink, the same material that was used as the lower contact layer in the active regions of all the cells presented here, was applied to the SnO₂ blocking layer as the interconnect contact layer. This resulted in values for the open circuit voltage, short circuit current and FF (1.440 V, 2.62 mA/cm2 and 0.363 respectively) that are comparable to those of Module I.

This result demonstrates that it is feasible to use the same material for the lower contact layer and for the interconnect contact layer, so that these can be printed onto the lower device component using a single processing step. This would make commercial production of these modules simpler and faster and therefore more cost effective.

For all the devices demonstrated here, the same material has been used for the transparent conductive adhesive layer and the interconnecting conductive adhesive layer. This proves the feasibility of a single processing step in which these two layers are printed onto the upper device component, which would make commercial production simpler, faster and more cost-effective.

1. Module of opto-electronic devices, which comprises a plurality of opto-electronic devices arranged on a first electrically insulating carrier substrate to define a plurality of interconnection regions between the opto-electronic devices, with each opto-electronic device comprising:
an upper device component that comprises a second electrically insulating carrier substrate and a counter electrode made of a metal, a conductive oxide or a conductive organic compound;
a lower device component that comprises a working electrode, a blocking layer, an active layer, a hole conducting layer and a lower contact layer, and
a conductive adhesive disposed between the upper device component and the lower device component, wherein the conductive adhesive disposed between the upper device component and the lower device component is a transparent conductive adhesive and an interconnecting conductive adhesive is provided in each interconnection region between, and in electrical contact with, the counter electrode of one opto-electronic device and a working electrode of an adjacent opto-electronic device for interconnecting the opto-electronic devices in series.

2. Module according to claim 1, wherein each opto-electronic device comprises a first upper contact layer between the counter electrode and the transparent conductive adhesive, preferably the first upper contact layer comprises a conductive polymer.

3. Module according to claim 1 or claim 2, wherein a second upper contact layer is provided in the interconnection region between the counter electrode and the interconnecting conductive adhesive, preferably the second upper contact layer comprises a conductive polymer.

4. Module according to any one of the preceding claims, wherein an interconnect contact layer is provided in the interconnect region between the interconnecting conductive adhesive and the blocking layer, preferably the interconnect contact layer comprises a conductive polymer.

5. Module according to claim 4, wherein the same material is used for the interconnect contact layer and for the lower contact layer.

6. Module according to any one of the preceding claims, wherein the conductive polymer comprises one or more of:
poly(3,4-ethylenedioxythiophene) poly(styrenesulfonate) and/or derivatives thereof;
polythiophenes and/or derivatives thereof;
polyanilines and/or derivatives thereof;
polypyroles and/or derivatives thereof.

7. Module according to any one of the preceding claims, wherein the transparent conductive adhesive comprises polyacrylates or derivatives thereof and one or more of:
poly(3,4-ethylenedioxythiophene) poly(styrenesulfonate) and/or derivatives thereof;
polythiophenes and/or derivatives thereof;
polyanilines and/or derivatives thereof;
polypyroles and/or derivatives thereof.

8. Module according to any one of the preceding claims, wherein the same material is used for the transparent conductive adhesive and the interconnecting conductive adhesive.

9. Module according to any one of claims 1-7, wherein the interconnecting conductive adhesive comprises an adhesive material and a conductive material comprising metal or metal alloy particles, allotropes of carbon or conductive polymers.

10. Module according to any one of the preceding claims, wherein the working electrode comprises a metallic sheet or foil, a metallic coating, or a coating that comprises metal oxides or doped metal oxides, carbon allotropes, metal or metal alloy particles or conductive polymers.

11. Module according to any one of the preceding claims, wherein the counter electrode is provided on or embedded in the second electrically insulating carrier substrate, preferably the counter electrode is provided as a metallic grid.

12. Module according to any one of the preceding claims, wherein the first electrically insulating carrier substrate and/or the second electrically insulating carrier substrate comprise glass, an insulating polymeric film or a metallic carrier substrate provided with an electrically insulating coating.

13. Method for manufacturing a module of opto-electronic devices according to any one of the preceding claims, which comprises the steps of:
providing a lower device component on a first electrically insulating carrier substrate in a first pattern to define a plurality of device regions and interconnection regions on the first electrically insulating carrier substrate, the lower device component comprising a working electrode, a blocking layer, an active layer, a hole conducting layer and a lower contact layer;
providing an upper device component that comprises a second electrically insulating carrier substrate and a counter electrode;
providing a transparent conductive adhesive on the upper device component in a second pattern to define a plurality of device regions and interconnection regions on the upper device component;
providing an interconnecting conductive adhesive in the interconnection regions of the upper device component;
curing the transparent conductive adhesive and the interconnecting conductive adhesive, and
aligning the device regions and interconnecting regions of the upper device component with the device regions and interconnecting regions of the lower device component and laminating the upper device component and the lower device component to form a module of opto-electronic devices that are electrically interconnected in series.

14. Method according to claim 13, wherein the transparent conductive adhesive and the interconnecting conductive adhesive are made of the same material and are deposited in a single processing step.

15. Method according to claim 13 or claim 14, wherein the lower contact layer and an interconnect contact layer provided in the interconnection region on the blocking layer are made of the same materials and are deposited in single processing step.
